(19) United States
(12) Patent Application Publication
(10) Pub. No.: US 2020/0266389 A1
(43) Pub. Date: Aug. 20, 2020

(54) LIGHT EMITTING PANEL

(71) Applicant: INT TECH CO., LTD., Hsinchu County (TW)

(72) Inventors: YEN-CHIH CHIANG, HSINCHU COUNTY (TW); LI-MIN HUANG, HSINCHU COUNTY (TW)

(21) Appl. No.: 16/279,679

(22) Filed: Feb. 19, 2019

(51) Int. Cl. H01L 51/52; H01L 27/32

(52) U.S. Cl. CPC H01L 51/5275; H01L 27/3244

(57) ABSTRACT

A light emitting panel includes a substrate, a plurality of light emitting devices disposed on the substrate, a protecting layer disposed on plurality of the light emitting devices, and an optical membrane disposed on the substrate. The plurality of light emitting devices include a first light emitting device configured to emit a first light beam, and a second light emitting device configured to emit a second light beam different from the first light beam in wavelengths. The optical membrane is substantially aligned with the first emitting device, and configured to modify an intensity of the first light beam output from the optical membrane with respect to an intensity of the first light beam output from the first light emitting device.

### TECHNICAL FIELD

The present disclosure is related to a light emitting panel, especially to an organic light emitting panel.

### BACKGROUND

Organic light emitting display has been used widely in most high end electron devices. However, due to the constraint of light emitting materials, OLED displays may show a faint remnant of an image even after a new image appears on the screen. In fact, one widely recognized remaining challenge is to improve device lifetime. In particular, the short operation time of devices that emit blue light are significant impediments to exploiting the full potential of OLED displays. Therefore, the OLED industry is seeking routes to address the above issues.

### SUMMARY

A light emitting panel includes a substrate, a plurality of light emitting devices disposed on the substrate, a protecting layer disposed on plurality of the light emitting devices, and an optical membrane disposed on the substrate. The plurality of light emitting devices include a first light emitting device configured to emit a first light beam, and a second light emitting device configured to emit a second light beam different from the first light beam in wavelengths. The optical membrane is substantially aligned with the first emitting device, and configured to modify an intensity of the first light beam output from the optical membrane with respect to an intensity of the first light beam output from the first light emitting device.

In some embodiments, the first light beam is substantially within a first wavelength range, the second light beam is substantially within a second wavelength range, and the first wavelength range is smaller than that of the second wavelength range. In some embodiments, a ratio of the intensity of the first light beam output from the optical membrane with respect to the intensity of the first light beam output from the first light emitting device is greater than 100%. In some embodiments, a transmittance of the optical membrane with respect to the first light beam is greater than 80%. In some embodiments, a light exiting surface of the optical membrane includes a flat surface. In some embodiments, a light exiting surface of the optical membrane includes a rough surface. In some embodiments, the protecting layer is between the first light emitting device and the optical membrane. In some embodiments, the optical membrane has a refractive index between 1.1 and 1.7. In some embodiments, the optical membrane is disposed between the protecting layer and the first light emitting device. In some embodiments, a conductivity of the optical membrane is less than 1×10⁻⁵ (S·m⁻¹).

In some embodiments, an effective light emitting area of the first light emitting device is greater than that of the second light emitting device. In some embodiments, a ratio of the effective light emitting area of first light emitting device to that of the second light emitting device is about 1.35. In some embodiments, the plurality of light emitting devices further comprise a third light emitting device configured to emit a third light beam different from the first light beam and the second light beam in wavelengths, wherein the third light beam is substantially within a third wavelength range, the third wavelength range is between the second wavelength range and the first wavelength range, and an effective light emitting area of the third light emitting device is greater than that of the second light emitting device. In some embodiments, a ratio of an effective light emitting area of the third light emitting device to that of the second light emitting device is ranged from about 0.7 to about 1.35.

In some embodiments, the first light beam is substantially within a first wavelength range, the second light beam is substantially within a second wavelength range, and the first wavelength range is greater than that of the second wavelength range. In some embodiments, a ratio of the intensity of the first light beam output from the optical membrane with respect to the intensity of the first light beam output from the first light emitting device is smaller than 100%. In some embodiments, a transmittance of the optical membrane with respect to the first light beam is less than 80%. In some embodiments, a transmittance of the optical membrane with respect to the second light beam is less than 80%.

### BRIEF DESCRIPTION OF THE DRAWINGS

FIG. 1 represents an intermediate product of a light emitting panel in accordance with some embodiments.

FIG. 2 is a top view of a light emitting panel in accordance with some embodiments.

FIG. 3 represents an intermediate product of a light emitting panel in accordance with some embodiments.

FIG. 4 represents an intermediate product of a light emitting panel in accordance with some embodiments.

FIG. 5 represents an intermediate product of a light emitting panel in accordance with some embodiments.

FIG. 6 represents an intermediate product of a light emitting panel in accordance with some embodiments.

FIG. 7 represents an intermediate product of a light emitting panel in accordance with some embodiments.

FIG. 8 represents an intermediate product of a light emitting panel in accordance with some embodiments.

### DETAILED DESCRIPTION OF THE DISCLOSURE

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of light emitting panels are provided. The structure of the light emitting panel may include at least two major levels. One level is configured as a light emitting level including an array of light emitting devices and provides luminescence for the panel. The light emitting devices can be made with organic or inorganic material. Another level is a circuit level which is electrically coupled to the light emitting level and vertically stacking with the light emitting level. The circuit level supplies power and control signals to the light emitting level in order to display the color or pattern as needed. In some embodiments, the arrangement of the light emitting devices in the array is determined through a photolithography operation.

An organic light emitting display panel includes organic light emitting diodes (OLED) in which the emissive electroluminescent layer is a film of organic compound that emits light in response to an electric current. OLEDs are used to create digital displays in devices such as television screens, computer monitors, portable systems such as smartphones, handheld game consoles and PDAs. However, one of the main problems of OLED panels is the limited lifetime of the OLED materials. In particular, blue OLEDs historically have had a shorter lifetime compare to red OLEDs and green OLEDs when used for display panels.

Additionally, as the OLED material used to produce blue light degrades significantly more rapidly than the materials that produce other colors such as red and green colors, blue light output will decrease relative to the other colors of light under the same drive current. This variation in the differential color output will change the color balance of the display and is much more noticeable than a decrease in overall luminance. This can be alleviated partially by adjusting color balance, but this may require advanced control circuits and interaction with the user, which is unacceptable for users.

Consequently, improvements to the efficiency and lifetime of blue OLEDs is vital to the success of OLEDs as replacements for LCD technology. In the present disclosure, a light emitting panel is provided to increase the lifespan of OLED displays. The light emitting panel increases the expected lifespan of OLEDs by improving light outcoupling, thus achieving the same brightness at a lower drive current. In addition, the light emitting panel of the present disclosure optimize the size of the R, G and B subpixels to reduce the current density through the subpixel in order to equalize lifetime at full luminance.

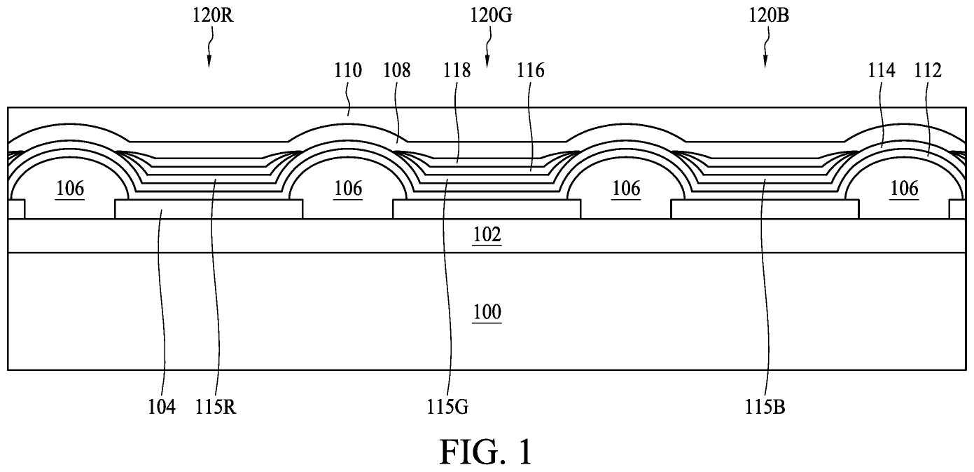

FIG. 1 represents an intermediate product of a light emitting panel in accordance with some embodiments. A substrate 100 is provided in a light emitting panel. The substrate 100 can include a glass, a semiconductive material such as silicon, III-V group compound, or other suitable material. In some embodiments, the substrate 100 includes graphene. In some embodiments, substrate 100 might be formed with a polymer matrix material. A dielectric layer 102 is optionally disposed over the substrate 100 as shown in FIG. 1. In some embodiments, the dielectric layer 102 may be made with silicon oxide, silicon nitride, silicon oxynitride, or other suitable materials.

In some embodiments, several first electrodes 104 are disposed over the dielectric layer 102 as shown in FIG. 1. The first electrodes 104 may include conductive materials. Specifically, the first electrodes can be metal such as Al, Cu, Ag, Au, W, etc. or metal alloy. In some embodiments, the first electrodes 104 can be transparent conductive material such as metal oxide. Examples of the transparent conductive material may include indium tin oxide (ITO), indium zinc oxide (IZO), aluminum-doped zinc oxide (AZO) and indium-doped cadmium oxide, etc. In some embodiments, the first electrodes 104 may be, but not limited to be, in direct contact with the dielectric layer 102. The first electrodes 104 are electrically connected to the light emitting devices respectively. In some embodiments, the first electrodes 104 are designed as an anode of the light emitting device.

In some embodiments, a pixel defining layer including a plurality of spacers 106 is formed on the substrate 100 and separates the first electrodes 104 from one another when viewed in a thickness direction of the light emitting panel. The spacers 106 can be optionally disposed over the dielectric layer 102 as in FIG. 1. In some embodiments, the spacers 106 partially cover the first electrodes 104 and leave a portion of the first electrodes 104 open to receive the light emitting devices. In some embodiments, the spacers 106 include polymeric material. In some embodiments, the spacers 106 include photosensitive material. In some embodiments, the spacers 106 are photo absorption material. In some embodiments, the spacers 106 are fluorine free, i.e. substantially contains no fluorine. In some embodiments, the spacers 106 are formed through a photolithography operation.

A plurality of light emitting devices are disposed on the substrate. The plurality of light emitting devices may have several sublayers stacked over the first electrodes 104. In some embodiments, each sublayer may be relatively thinner than the first electrodes 104. In some embodiments, a thickness of a sublayer in the light emitting devices is in nanometer scale. In some embodiments, the light emitting device is an organic light emitting device. More specifically, the plurality of light emitting devices may have a first carrier injection layer 112, a first carrier transportation layer 114, a light emitting layer, a second carrier transportation layer 116 and a second carrier injection layer 118.

The first carrier injection layer 112 disposed over the exposed surfaces of the spacers 106 and the first electrodes 104. The first carrier injection layer 112 is continuously lining along the exposed surfaces. More specifically, the exposed surface of each first electrode 104 is configured as an effective light emitting area for a light emitting device. In this embodiment, all light emitting devices use a common first carrier injection layer 112. In some embodiments, the first carrier injection layer 112 is for hole injection. In some embodiments, the first carrier injection layer 112 is for electron injection. The first carrier injection layer 112 continuously overlies the spacers 106 and the first electrodes 104 as in FIG. 1. Optionally, the first carrier injection layer 112 is in contact with the spacers 106. In one embodiment, the first carrier injection layer 112 is in contact with the first electrodes 104. In some embodiments, the first carrier injection layer 112 is organic.

The first carrier transportation layer 114 is disposed over the spacers 106 and the first electrodes 104. The first carrier injection layer 112 is disposed under the first carrier transportation layer 114. The first carrier transportation layer 114 is continuously lining along the first carrier injection layer 112. In this embodiment, all light emitting devices use a common first carrier transportation layer 114. In some embodiments, the first carrier transportation layer 114 is for hole transportation. In some embodiments, the first carrier transportation layer 114 is for electron transportation. The first carrier transportation layer 114 continuously overlies several spacers 106 and the first electrodes 104. Optionally, the first carrier transportation layer 114 is in contact with the first carrier injection layer 112. In some embodiments, the first carrier transportation layer 114 is organic.

A light emitting layer is formed above the surfaces of the first electrodes 104. In some embodiments, the light emitting layer may include a red light emitting layer 115R, a green light emitting layer 115G, and a blue light emitting layer 115B. The red light emitting layer 115R, the green light emitting layer 115G, and the blue light emitting layer 115B are respectively disposed on the first carrier transportation layer 114. In some embodiments, a portion of the light emitting layer is formed on or over the first electrodes 104 through the opening, and another portion of the light emitting layer may be formed on or over the pixel defining layer as illustrated in FIG. 1.

A second carrier transportation layer 116 is disposed on the red light emitting layer 115R, the green light emitting layer 115G, and the blue light emitting layer 115B respectively. In some embodiments, the second carrier transportation layer 116 is for electron transportation. In some embodiments, the second carrier transportation layer 116 is for hole transportation. The second carrier transportation layer 116 partially overlies the spacers 106 and the first electrodes 104. In some embodiments, the second carrier transportation layer 116 is organic.

A second carrier injection layer 118 is disposed on the second carrier transportation layer 116. The second carrier injection layer 118 is lining along the exposed surfaces of the second carrier transportation layer 116. In some embodiments, the second carrier injection layer 118 is for electron injection. In some embodiments, the second carrier injection layer 118 is for hole injection. In some embodiments, the second carrier injection layer 118 may be, but is not limited to, in contact with the second carrier transportation layer 116. In some embodiments, the second carrier injection layer 118 is organic.

A plurality of second electrodes 108 are formed above the light emitting layer. The second electrodes may include conductive materials. In some embodiments, the second electrodes 108 may be provided as a transmissive electrode. For example, the second electrodes 108 may be formed by a thin transmissive layer which is made of metal oxides. Examples of the transparent conductive material may include indium tin oxide (ITO), indium zinc oxide (IZO), aluminum-doped zinc oxide (AZO) and indium-doped cadmium oxide, etc. In some embodiments, the second electrodes 108 may be provided as a transflective electrode. For example, the second electrodes 108 may be formed by a thin transflective layer which is made of metal having a low work function, that is, alkali metal such as lithium (Li) and cesium (Cs), alkaline earth metal such as magnesium (Mg), calcium (Ca) and strontium (Sr), and compounds thereof. A transparent conductive layer made of indium tin oxide (ITO) and indium zinc oxide (IZO) may be further included above or below the metal transflective layer. In some embodiments, the second electrodes 108 may be designed as cathodes of the light emitting devices.

The protecting layer 110 for protecting the light emitting layer from an external environment such as moisture or oxygen may be provided on the second electrodes 108. The protecting layer 110 may be formed of a thin film encapsulation layer in which a plurality of organic layers and inorganic layers cross each other and are laminated or a transparent substrate such as encap glass. In some embodiments, the protecting layer 110 may include a plurality of organic layers and a plurality of inorganic layers which are alternately laminated. The organic layers may be formed by containing acrylate-based materials and the inorganic layers may be formed by containing oxide-based materials.

As shown in FIG. 1, the light emitting devices include a first light emitting device 120B configured to emit a first light beam and a second light emitting device 120R configured to emit a second light beam different from the first light beam in wavelengths. In addition, the first light beam is substantially within a first wavelength range, the second light beam is substantially within a second wavelength range. In some embodiments, the light emitting devices further includes a third light emitting device 120G configured to emit a third light beam different from the first light beam and the second light beam in wavelengths. In some embodiments, the first wavelength range is smaller than that of the second wavelength range. Particularly, the first wavelength range is 430-470 nm, the second wavelength range is 620-750 nm and the third wavelength range is 495-570 nm. More specifically, the first light beam is blue light, the second light beam is red light, and the third light beam is green light.

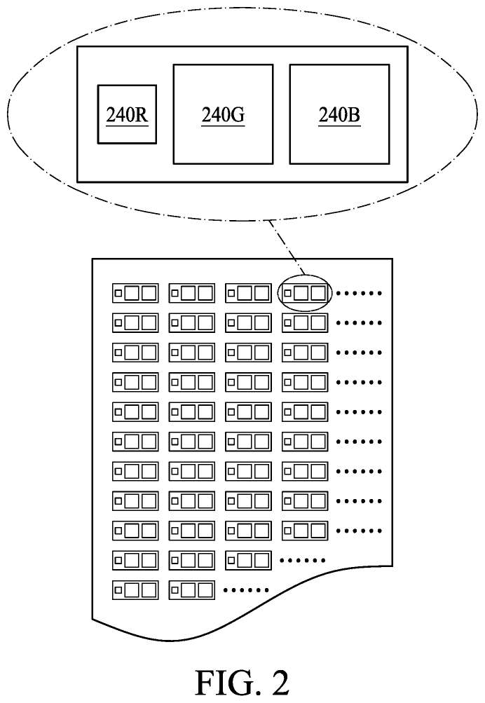

FIG. 2 is a top view of a light emitting panel in accordance with some embodiments. The light emitting panel includes the substrate 100 and a pixel array. The pixel array includes a first sub pixel 240B configured to emit the blue light beam, a second sub pixel 240R configured to emit the red light beam, and a third sub pixel 240G configured to emit the green light beam. The first sub pixel 240B includes the first light emitting device 120B, the second sub pixel includes the second light emitting device 120R, and the third sub pixel 240G includes the third light emitting device 120G respectively. In some embodiments, an effective light emitting area of the first sub pixel 240B is greater than that of the second sub pixel 240R. Moreover, the arrangement of the first sub pixel 240B, the second sub pixel 240R and the third sub pixel 240G can be any geometric arrangement. In addition, the shape of the first sub pixel 240B, the second sub pixel 240R and the third sub pixel 240G can be any rectangle or circle.

In some embodiments, a ratio of the effective light emitting area of the first sub pixel 240B to that of the second sub pixel 240R is greater than 1. Specifically, the ratio of the effective light emitting area of the first sub pixel 240B to that of the second sub pixel 240R is about 1.35. In some embodiments, a ratio of an effective light emitting area of the third sub pixel 240G to that of the second sub pixel 240R is ranged from about 0.5 to about 1.5. In particular, the ratio of an effective light emitting area of the third sub pixel 240G to that of the second sub pixel 240R is ranged from about 0.7 to about 1.35. The size of the subpixels 240R, 240G and 240B are optimized to reduce the current density through the subpixels in order to equalize lifetime at full luminance. Consequently, the degradation rate of the sub pixels 240R, 240G and 240B may become balanced, and the life span of the light emitting panel may last longer.

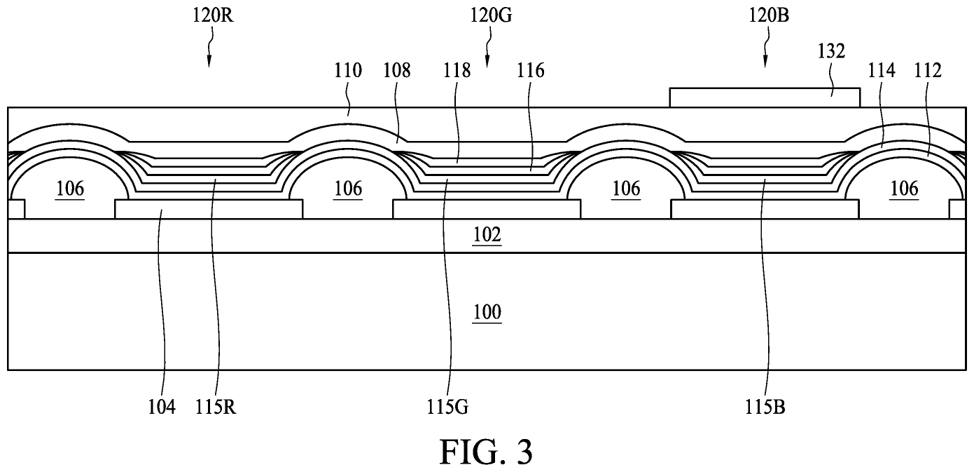

FIG. 3 represents an intermediate product of a light emitting panel in accordance with some embodiments. An optical membrane 132 is disposed on the substrate 100, wherein the optical membrane 132 is substantially aligned with the first light emitting device 120B, and configured to modify an intensity of the first light beam output from the optical membrane 132 with respect to an intensity of the first light beam output from the first light emitting device 120B. It is worth noting that the optical membrane 132 may be described in other terms, such as a light modification layer, a lens layer, micro-lens, or light adjustable lens.

In some embodiments, the optical membrane 132 may be disposed on the substrate 100 by a plasma treatment process, a nanoimprint lithography process or a laser melting process. In some embodiments, a light exiting surface of the optical membrane 132 includes a flat surface. Alternatively, the light exiting surface of the optical membrane 132 includes an orderly arranged microstructure array. In some embodiments, the light exiting surface of the optical membrane 132 includes a rough surface. In addition, the light exiting surface of the optical membrane 132 includes a randomly arranged microstructure array. In order to increase the output light intensity of the first light emitting device 120B, a transmittance of the optical membrane 132 with respect to the first light beam may be greater than 50%. In some embodiments, a transmittance of the optical membrane 132 with respect to the first light beam may be greater than 80%.

As shown in FIG. 3, the protecting layer 110 is disposed between the first light emitting device 120B and the optical membrane 132. In addition, the optical membrane 132 may have a refractive index different from the protecting layer 110. Refraction occurs when light goes through the interface of the protecting layer 110 and the optical membrane 132 since their refractive index are different. In some embodiments, the refractive index of the optical membrane 132 may be greater than the refractive index of the protecting layer 110. In some embodiments, the optical membrane 132 may have a refractive index between 1.1 and 1.7. The optical membrane 132 may increase amount of emission light by scattering the light generated from the first light emitting device 120B. In some embodiments, a ratio of the intensity of the first light beam output from the optical membrane 132 with respect to the intensity of the first light beam output from the first light emitting device 120B may be greater than 100%. More specifically, a ratio of the intensity of the first light beam output from the optical membrane 132 with respect to the intensity of the first light beam output from the first light emitting device 120B may be greater than 120%

In the present disclosure, the optical membrane 132 is disposed on the protecting layer 110. In some embodiments, the optical membrane 132 may be disposed in the protecting layer 110. In other words, the protecting layer 110 may include sublayers, and the optical membrane 132 is within one of the sublayers. Consequently, the protecting layer 110 is not a homogeneous layer, but a heterogeneous layer including the optical membrane 132. In some embodiments, the optical membrane 132 may be disposed above the first light emitting device 120B. More specifically, the optical membrane 132 may be disposed in any layer of the light emitting panel as long as the optical membrane 132 substantially aligned with the first light emitting device 120B. In addition, an effective light emitting area of the optical membrane 132 may be changed according to the effective light emitting area of the first light emitting device 120B. Specifically, the effective light emitting area of the optical membrane 132 may be substantially aligned with the effective light emitting area of the first light emitting device 120B.

The optical membrane 132 may increase the light efficiency of the first light emitting device 120B by increasing the amount of emission light. In other words, the optical membrane 132 helps deliver light from the first light emitting device 120B in the light emitting panel of the present disclosure throughout the uppermost surface more efficiently than a current light emitting panel's. Since the light efficiency of the first light emitting device 120B is increased, less current is needed to drive the first light emitting device 120B. In particular, the same brightness of the first light emitting device 120B is achieved at a lower drive current. In addition, higher brightness of the first light emitting device 120B may be achieved at a lower drive current. In some embodiments, a ratio of the intensity of the first light beam output from the optical membrane 132 with respect to the intensity of the first light beam output from the first light emitting device 120B greater than 100% is achieved at a lower drive current. Specifically, the drive current may be reduced to 80% compared to a drive current of a light emitting panel without the optical membrane 132. Since the drive current is reduced, less degradation may occur in the first light emitting device 120B. Therefore, the expected lifetime of the first light emitting device 120B may be longer.

In some embodiments, the arrangement of the pixel array in the light emitting panel of FIG. 3 may have the same design as shown in FIG. 2. Specifically, the ratio of the effective light emitting area of the first light emitting device 120B to that of the second light emitting device 120R is about 1.35. Moreover, the ratio of an effective light emitting area of the third light emitting device 120G to that of the second light emitting device 120R is ranged from about 0.7 to about 1.35.

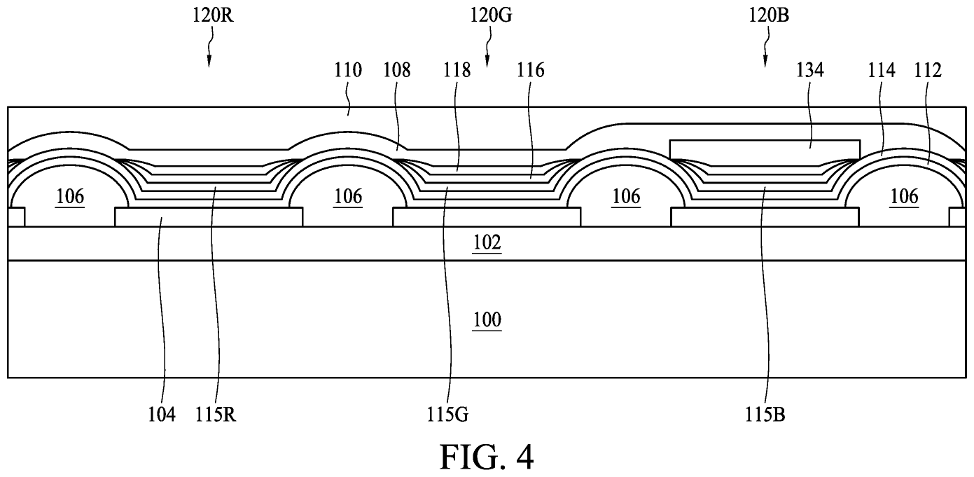

Other alternatives or embodiments may present without departure from the spirit and scope of the present disclosure. FIG. 4 represents an intermediate product of a light emitting panel in accordance with some embodiments. The optical membrane 134 may be disposed between the protecting layer 110 and the first light emitting device 120B. In addition, the optical membrane 134 may have a refractive index different from the protecting layer 110. Refraction occurs when light goes through the interface of the protecting layer 110 and the optical membrane 134 since their refractive index are different. In some embodiments, the refractive index of the optical membrane 134 may be smaller than the refractive index of the protecting layer 110. In some embodiments, the optical membrane 134 may be in contact with the first light emitting device 120B. In some embodiments, a conductivity of the optical membrane 134 may be less than that of the second electrodes 108. Specifically, the conductivity of the optical membrane 134 may be less than that of the cathode of the light emitting device 120B. In particular, the conductivity of the optical membrane 134 may be less than 1×10⁻⁵ (S·m⁻¹). In some embodiments, the arrangement of the pixel array in the light emitting panel of FIG. 4 may have the same design as shown in FIG. 2. Specifically, the ratio of the effective light emitting area of the first light emitting device 120B to that of the second light emitting device 120R is about 1.35. Moreover, the ratio of an effective light emitting area of the third light emitting device 120G to that of the second light emitting device 120R is ranged from about 0.7 to about 1.35.

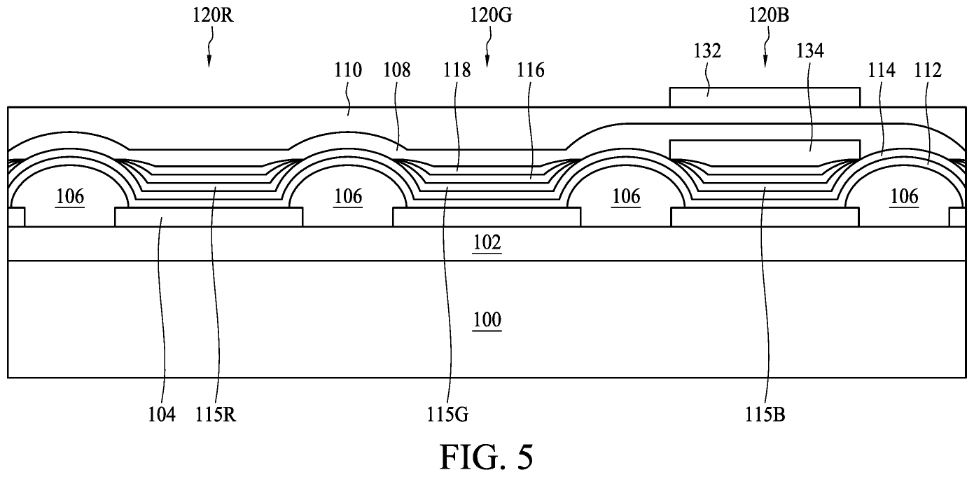

FIG. 5 represents an intermediate product of a light emitting panel in accordance with some embodiments. Different from FIG. 3, the light emitting panel may include another optical membrane 134 disposed between the protecting layer 110 and the first light emitting device 120B. The optical membrane 134 is substantially aligned with the optical membrane 132 and the first light emitting device 120B. In some embodiments, the optical membrane 134 may be in contact with the first light emitting device 120B. In addition, a conductivity of the optical membrane 134 may be less than 1×10⁻⁵ (S·m⁻¹). In some embodiments, the arrangement of the pixel array in the light emitting panel of FIG. 5 may have the same design as shown in FIG. 2. Specifically, the ratio of the effective light emitting area of the first light emitting device 120B to that of the second light emitting device 120R is about 1.35. Moreover, the ratio of an effective light emitting area of the third light emitting device 120G to that of the second light emitting device 120R is ranged from about 0.7 to about 1.35.

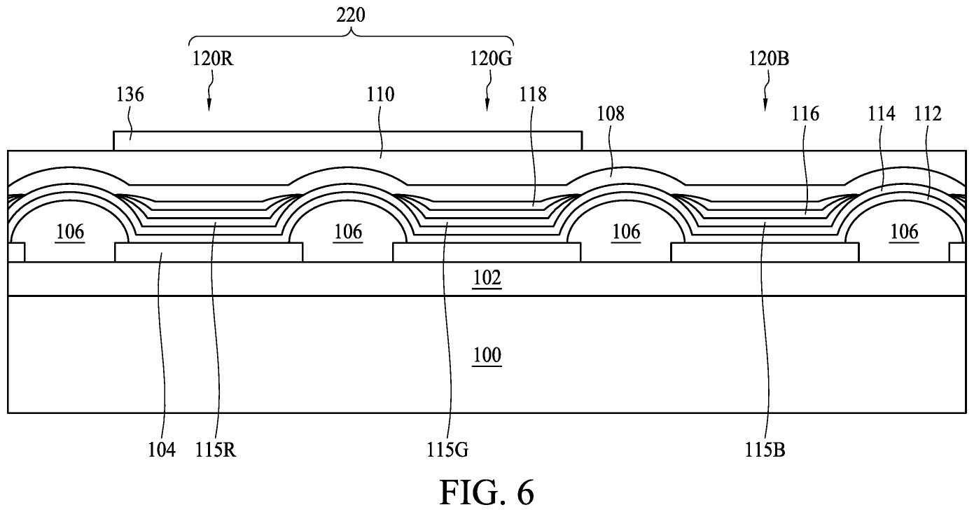

FIG. 6 represents an intermediate product of a light emitting panel in accordance with some embodiments. A light emitting device 220 is disposed on the substrate 110. In the present disclosure, the light emitting device 220 may include the second light emitting device 120R and the third light emitting device 120G, but not limited thereto. The light emitting device 220 may be the second light emitting device 120R or the third light emitting device 120G only. An optical membrane 136 may be disposed on the substrate 100, wherein the optical membrane 136 may be substantially aligned with the light emitting device 220, and configured to modify an intensity of the light beam output from the optical membrane 136 with respect to an intensity of the light beam output from the light emitting device 220. In this embodiment, the wavelength range of the light emitting device 220 may be greater than that of the wavelength range of the first light emitting device 120B. More Specifically, the wavelength range of the light emitting device 220 may be 500-670 nm, and the wavelength range of the first light emitting device 120B is 430-470 nm. Particularly, the light beam of the first light emitting device may be blue light, and the light beam of the light emitting device 220 may be red light or green light.

In some embodiments, a transmittance of the optical membrane 136 with respect to the light beam emitted from the light emitting device 220 is less than 80%. The optical membrane 132 may decrease the amount of emission light by absorbing the light generated from the light emitting device 220. In some embodiments, a ratio of the intensity of the light beam output from the optical membrane 136 with respect to the intensity of the light beam output from the light emitting device 220 is smaller than 100%.

As shown in FIG. 6, the protecting layer 110 is disposed between the light emitting device 220 and the optical membrane 136. The optical membrane 136 may have a refractive index between 1.1 and 1.7. In addition, a refractive index of the optical membrane 136 may be similar to a refractive index of organic materials. Specifically, the refractive index of the optical membrane 136 may be ranged from about 1.4 to about 1.6, and the refractive index of the optical membrane 136 may be ranged from about 1.4 to about 1.5. In some embodiments, a refractive index of the optical membrane 136 may be smaller than a refractive index of organic materials. Accordingly, the optical membrane 136 may decrease the light efficiency of the light emitting device 220 by reflecting the amount of emission light. In some embodiments, the optical membrane 136 may include materials that absorb the emission light from the light emitting device 220. In other words, the optical membrane 136 may be a blue color filter, which absorbs part of the red light and the green light. Specifically, the optical membrane 136 may absorb 20% of the amount of emission light from the light emitting device 220. Accordingly, the optical membrane 136 may decrease the light efficiency of the light emitting device 220 by absorbing the amount of emission light. Since the light efficiency of the light emitting device 220 is decreased, the lifetime of the each light emitting device may be equalized under the same drive current. In some embodiments, the arrangement of the pixel array in the light emitting panel of FIG. 6 may have the same design as shown in FIG. 2. Specifically, the ratio of the effective light emitting area of the first light emitting device 120B to that of the second light emitting device 120R is about 1.35. Moreover, the ratio of an effective light emitting area of the third light emitting device 120G to that of the second light emitting device 120R is ranged from about 0.7 to about 1.35.

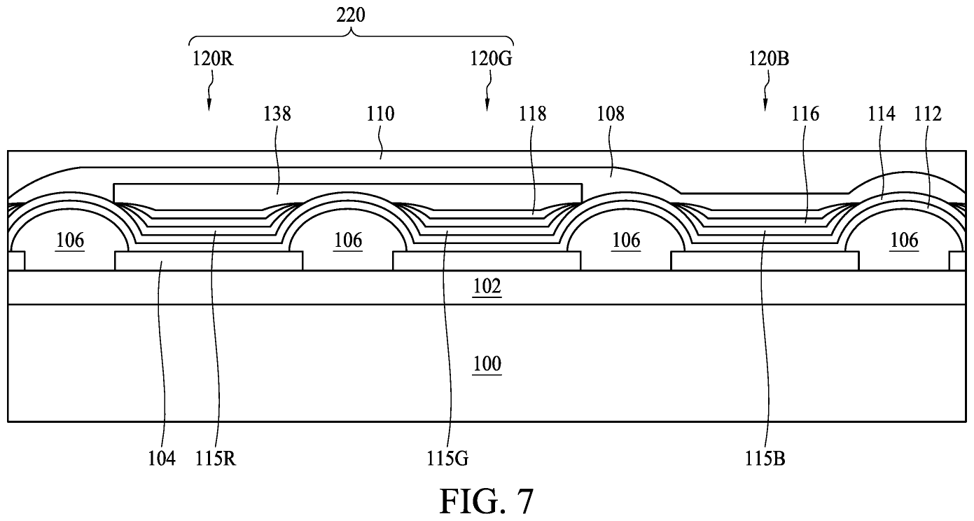

FIG. 7 represents an intermediate product of a light emitting panel in accordance with some embodiments. The optical membrane 138 may be disposed between the protecting layer 110 and the light emitting device 220. In some embodiments, the optical membrane 138 may be in contact with the light emitting device 220. Particularly, a transmittance of the optical membrane 138 with respect to the blue light (i.e. 430-470 nm) is less than 80%. The optical membrane 136 may decrease the light efficiency of the light emitting device 220 by absorbing the amount of emission light. Furthermore, a conductivity of the optical membrane 138 may be less than 1×10⁻⁵ (S·m⁻¹). In addition, the optical membrane 138 may have a refractive index different from the light emitting device 220. Refraction occurs when light goes through the interface of the light emitting device 220 and the optical membrane 138 since their refractive index are different. In some embodiments, the refractive index of the optical membrane 138 may be smaller than the refractive index of organic materials in the light emitting device 220. Moreover, the optical membrane 138 may be in nanometer scale. Specifically, the thickness of the optical membrane 138 is ranged from about 1 nm to about 100 nm. In some embodiments, the arrangement of the pixel array in the light emitting panel of FIG. 7 may have the same design as shown in FIG. 2. Specifically, the ratio of the effective light emitting area of the first light emitting device 120B to that of the second light emitting device 120R is about 1.35. Moreover, the ratio of an effective light emitting area of the third light emitting device 120G to that of the second light emitting device 120R is ranged from about 0.7 to about 1.35.

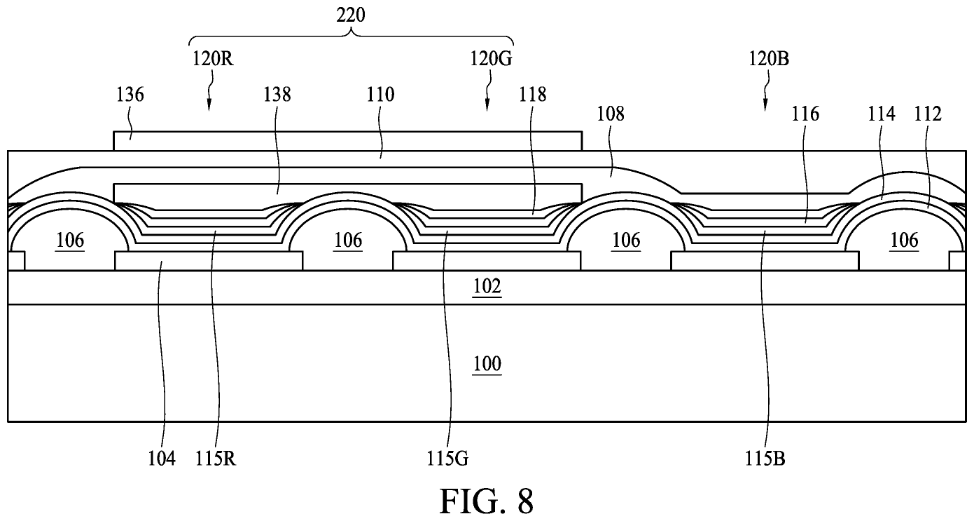

FIG. 8 represents an intermediate product of a light emitting panel in accordance with some embodiments. Different from FIG. 7, the light emitting panel may include another optical membrane 136 disposed above the protecting layer 110 and the first light emitting device 120B. The optical membrane 136 is substantially aligned with the optical membrane 138 and the light emitting device 220. In some embodiments, a refractive index of the optical membrane 136 may be greater than a refractive index of organic materials. In some embodiments, the arrangement of the pixel array in the light emitting panel of FIG. 8 may have the same design as shown in FIG. 2. Specifically, the ratio of the effective light emitting area of the first light emitting device 120B to that of the second light emitting device 120R is about 1.35. Moreover, the ratio of an effective light emitting area of the third light emitting device 120G to that of the second light emitting device 120R is ranged from about 0.7 to about 1.35.

In the present disclosure, several embodiments of a light emitting panel are provided to increase the lifespan of OLED displays. The light emitting panel increases the expected lifespan of OLEDs by using an optical membrane, thus achieving the same brightness at a lower drive current. In addition, the light emitting panel of the present disclosure optimize the size of the R, G and B subpixels to reduce the current density through the subpixel in order to equalize lifetime at full luminance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A light emitting panel, comprising:
a substrate;
a plurality of light emitting devices disposed on the substrate, wherein the plurality of light emitting devices comprise:
a first light emitting device configured to emit a first light beam; and
a second light emitting device configured to emit a second light beam different from the first light beam in wavelengths;
a protecting layer disposed on the first light emitting device and the second light emitting device; and
an optical membrane disposed on the substrate, wherein the optical membrane is substantially aligned with the first emitting device, and configured to modify an intensity of the first light beam output from the optical membrane with respect to an intensity of the first light beam output from the first light emitting device.

2. The light emitting panel in claim 1, wherein the first light beam is substantially within a first wavelength range, the second light beam is substantially within a second wavelength range, and the first wavelength range is smaller than that of the second wavelength range.

3. The light emitting panel in claim 2, wherein a ratio of the intensity of the first light beam output from the optical membrane with respect to the intensity of the first light beam output from the first light emitting device is greater than 100%.

4. The light emitting panel in claim 2, wherein a transmittance of the optical membrane with respect to the first light beam is greater than 80%.

5. The light emitting panel in claim 2, wherein a light exiting surface of the optical membrane includes a flat surface.

6. The light emitting panel in claim 2, wherein a light exiting surface of the optical membrane includes a rough surface.

7. The light emitting panel in claim 2, wherein the protecting layer is between the first light emitting device and the optical membrane.

8. The light emitting panel in claim 7, wherein the optical membrane has a refractive index between 1.1 and 1.7.

9. The light emitting panel in claim 2, wherein the optical membrane is disposed between the protecting layer and the first light emitting device.

10. The light emitting panel in claim 9, wherein a conductivity of the optical membrane is less than a conductivity of a cathode of the light emitting devices.

11. The light emitting panel in claim 2, wherein an effective light emitting area of the first light emitting device is greater than that of the second light emitting device.

12. The light emitting panel in claim 11, wherein a ratio of the effective light emitting area of first light emitting device to that of the second light emitting device is about 1.35.

13. The light emitting panel in claim 2, wherein the plurality of light emitting devices further comprise a third light emitting device configured to emit a third light beam different from the first light beam and the second light beam in wavelengths, wherein the third light beam is substantially within a third wavelength range, the third wavelength range is between the second wavelength range and the first wavelength range, and an effective light emitting area of the third light emitting device is greater than that of the second light emitting device.

14. The light emitting panel in claim 11, wherein a ratio of an effective light emitting area of the third light emitting device to that of the second light emitting device is ranged from about 0.7 to about 1.35.

15. The light emitting panel in claim 1, wherein the first light beam is substantially within a first wavelength range, the second light beam is substantially within a second wavelength range, and the first wavelength range is greater than that of the second wavelength range.

16. The light emitting panel in claim 15, wherein a ratio of the intensity of the first light beam output from the optical membrane with respect to the intensity of the first light beam output from the first light emitting device is smaller than 100%.

17. The light emitting panel in claim 15, wherein the protecting layer is between the first light emitting device and the optical membrane.

18. The light emitting panel in claim 17, wherein a transmittance of the optical membrane with respect to the first light beam is less than 80%.

19. The light emitting panel in claim 15, wherein the optical membrane is disposed between the protecting layer and the first light emitting device.

20. The light emitting panel in claim 19, wherein a conductivity of the optical membrane is less than a conductivity of a cathode of the light emitting devices.

21. The light emitting panel in claim 19, wherein a transmittance of the optical membrane with respect to the second light beam is less than 80%.
